(19) United States
(12) Patent Application Publication
(10) Pub. No.: US 2019/0221764 A1
(43) Pub. Date: Jul. 18, 2019

(54) PHOTOABSORBER AND SOLAR CELL COMPRISING THE SAME

(71) Applicant: Panasonic Intellectual Property Management Co., Ltd., Osaka (JP)

(72) Inventors: TAKEYUKI SEKIMOTO, Osaka (JP); MICHIO SUZUKA, Kyoto (JP)

(21) Appl. No.: 16/166,344

(22) Filed: Oct. 22, 2018

(30) Foreign Application Priority Data
Jan. 17, 2018 (JP) 2018-005653

(51) Int. Cl. H01L 51/44; H01L 51/42; H01L 31/055

(52) U.S. Cl. CPC H01L 51/447; H01L 51/441; H01L 31/055; H01L 51/4233; H01L 51/4226

(57) ABSTRACT

The present disclosure provides a photoabsorber which has a perovskite crystal structure and is represented by the composition formula ABX₃, wherein A is a monovalent cation including formamidinium cation A¹ and a nitrogen-containing cation A²; the nitrogen-containing cation A² has a larger ionic radius than the formamidinium cation A¹; B is a divalent cation including a Sn cation; and X is a halogen anion. The photoabsorber according to the present disclosure improves conversion efficiency of the perovskite solar cell.

### BACKGROUND

### 1. Technical Field

The present disclosure relates to a photoabsorber and a perovskite solar cell comprising the same.

### 2. Description of the Related Art

A perovskite solar cell has been recently researched and developed. In the perovskite solar cell, a perovskite compound formed of a perovskite crystal structure represented by the composition formula ABX₃ (where A is a monovalent cation, B is a divalent cation, and X is a halogen anion) or a structure similar thereto is used as a photoabsorber.

Non-Patent Literature 1 discloses that a perovskite compound represented by (HC(NH₂)₂)SnI₃ (hereinafter, referred to as “FASnI₃”) is used as a photoabsorber of the perovskite solar cell. Non-Patent Literature 2 discloses theoretically-calculated stability of Sn²⁺ included in two perovskite compounds represented by FASnI₃ and (CH₃NH₃)SnI₃ (hereinafter, referred to as “MASnI₃”).

### CITATION LIST

### Non-Patent Literature

Non-Patent Literature 1: Teck Ming Koh et al., “Formamidinium tin-based perovskite with low Eg for photovoltaic applications”, Journal of Materials Chemistry. A, July 2015, Vol. 3, p. 14996-15000

Non-Patent Literature 2: Tingting Shi et al., “Effects of organic cations on the defect physics of tin halide perovskites”, Journal of Materials Chemistry A, June 2017, Vol. 5, p. 15124-15129

Non-Patent Literature 3: Yangyang Dang et al., “Formation of Hybrid Perovskite Tin Iodide Single Crystals by Top-Seeded Solution Growth”, Angewandte Chemie International Edition, 2016, vol. 55, p. 3447-3450

### SUMMARY

An object of the present disclosure is to provide a photoabsorber capable of improving conversion efficiency of the perovskite solar cell.

The present disclosure provides a photoabsorber which has a perovskite crystal structure and is represented by the composition formula ABX₃, wherein A is a monovalent cation including formamidinium cation A¹ and a nitrogen-containing cation A²; the nitrogen-containing cation A² has a larger ionic radius than the formamidinium cation A¹; B is a divalent cation including a Sn cation; and X is a halogen anion.

The present disclosure provides a photoabsorber capable of improving conversion efficiency of the perovskite solar cell.

### BRIEF DESCRIPTION OF THE DRAWINGS

FIG. 1 is a cross-sectional view of the first example of the solar cell according to the present embodiment.

FIG. 2 is a cross-sectional view of the second example of the solar cell according to the present embodiment.

FIG. 3 is a cross-sectional view of the third example of the solar cell according to the present embodiment.

FIG. 4 is a cross-sectional view of the fourth example of the solar cell according to the present embodiment.

FIG. 5 is a cross-sectional view of the fifth example of the solar cell according to the present embodiment.

FIG. 6 is a cross-sectional view of the sixth example of the solar cell according to the present embodiment.

FIG. 7 is a cross-sectional view of the seventh example of the solar cell according to the present embodiment.

FIG. 8 is a graph showing the results of the XRD measurement of the compounds prepared in the inventive examples 1-7 and the comparative example 1.

FIG. 9 is a graph showing the results of the XRD measurement of the compounds prepared in the inventive examples 15-17 and the comparative examples 3 and 5.

FIG. 10 is a graph showing a relation between a difference Or and the lattice constant in the inventive examples 8-20 and the comparative examples 2 and 4.

FIG. 11 is a graph showing a relation between the difference Or and the diffraction angle 2θ of the position of the cubical crystal (100) peak in the inventive examples 8-20 and the comparative examples 2 and 4.

FIG. 12 is a graph showing a relation between the lattice constant of the perovskite compounds included in the photoabsorber layers of the solar cells fabricated in the inventive examples 8-14 and 18-21 and normalized conversion efficiency of the solar cells.

### DETAILED DESCRIPTION OF THE EMBODIMENT

Hereinafter, the embodiment of the present disclosure will be described with reference to the drawings.

(Findings Which Established the Foundation of the Present Disclosure)

The findings which established the foundation of the present disclosure will be described below.

Non-Patent Literature 2 discloses that binding between a 5s orbital of Sn and a 5p orbital of I is weakened with an increase in size of the cation of A site of a perovskite compound, that the weakening shifts an anti-bonding orbital to a lower energy side, and that formation energy of Sn vacancy is increased.

As just described, according to Non-Patent Literature 2, with regard to the perovskite compound in which Sn²⁺ is located at B site thereof, as the size of the cation of the A site is larger, the formation energy of the Sn vacancy is increased. On the basis of the disclosure of Non-Patent Literature 2, the present inventors believe that the number of the Sn vacancy is decreased when the size of the cation of the A site is large, with regard to the perovskite compound in which Sn²⁺ is located at the B site thereof.

As a result, the present inventors found a novel FASnI₃ perovskite compound capable of improving performance of a solar cell.

(Photoabsorber)

The photoabsorber according to the present embodiment has a perovskite crystal structure and is represented by the composition formula ABX₃. Hereinafter, a compound which has a perovskite crystal structure and is represented by the composition formula ABX₃ is referred to as a perovskite compound. Pursuant to the expression used conventionally for the perovskite compound, A, B, and X are referred to as “A site”, “B site”, and “X site” in the instant specification, respectively.

A includes A¹ and A², each of which is a monovalent cation. A¹ is a formamidinium cation. A is a monovalent cation including the formamidinium cation A¹ and a nitrogen-containing cation A². The nitrogen-containing cation A² has a larger ionic radius than the formamidinium cation. Hereinafter, the formamidinium cation is referred to as “FA⁺” or “FA”.

In other words, the A site is occupied by FA and A². As just described, a part of the A site of the perovskite compound according to the present embodiment includes an organic compound (namely, A²) having a larger ionic radius than FA.

The part of the A site may be occupied by a monovalent cation other than A¹ and A²; however, it is desirable that A is represented by the composition formula A¹₍₁₋ₓ₎A²ₓ. Therefore, it is desirable that the photoabsorber according to the present embodiment is represented by the composition formula A¹₍₁₋ₓ₎A²ₓBX₃. The value of x is more than 0 and less than 1. Desirably, the value of x is not less than 0.05 and not more than 0.5.

In the instant specification, the word “photoabsorber” means “light absorbing material”. In addition, the photoabsorber serves as a photoelectric conversion material.

A² is not limited, as long as A² is a monovalent cation having a larger ionic radius than the formamidinium cation. FA has an ionic radius of 0.253 nanometers. As one example, A² is a cation of an organic compound having an ionic radius of not less than 0.274 nanometers and not more than 0.315 nanometers. An example of A² is at least one selected from the group consisting of an ethylammonium cation and a guanidinium cation. The ethylammonium cation has an ionic radius of 0.274 nanometers. The guanidinium cation has an ionic radius of 0.278 nanometers. Hereinafter, the ethylammonium cation is referred to as “EA⁺” or “EA”. The guanidinium cation is referred to as “GA⁺” or “GA”.

As just described, it is desirable that the organic compound contains a nitrogen atom in the inside thereof. In the instant specification, the cation of the organic compound containing a nitrogen atom in the inside thereof is referred to as “nitrogen-containing” cation.

B is a divalent cation including a Sn cation (namely, Sn²⁺). Desirably, B is a Sn cation (namely, Sn²⁺). In other words, it is desirable that the B site is occupied by the Sn cation. Therefore, the photoabsorber according to the present embodiment is represented by the composition formula ASnX₃.

X is a halogen anion. In other words, X is at least one selected from the group consisting of a chloride ion represented by the chemical formula Cl⁻, a bromide ion represented by the chemical formula Br⁻, and an iodide ion represented by the chemical formula r. It is desirable that X is an iodide ion.

The photoabsorber according to the present embodiment contains the above perovskite compound mainly. In the instant specification, “contain mainly” means that the photoabsorber according to the present embodiment contains the above perovskite compound at a mass percent of not less than 90% (desirably, not less than 95%). The photoabsorber according to the present embodiment may be formed of the above perovskite compound.

The photoabsorber according to the present embodiment may contain impurities. The photoabsorber according to the present embodiment may further contain a compound other than the above perovskite compound.

The present inventors believe that the organic compound (namely, A²) having a larger ionic radius than FA weakens the binding between a 5s orbital of Sn and a 5p orbital of I. As a result, compared to FASnI₃, the anti-bonding orbital is shifted to a lower energy side. For this reason, the present inventors believe that the number of Sn vacancies is decreased in the perovskite compound. As a result, the carrier recombination is prevented.

The perovskite compound according to the present embodiment has a larger lattice constant than a perovskite compound FASnI₃ which does not include A². The perovskite compound FASnI₃ which does not include A² has a lattice constant of 0.6315 nanometers. The perovskite compound according to the present embodiment may have a lattice constant of more than 0.6315 nanometers and not more than 0.6363 nanometers. In the instant specification, the perovskite compound FASnI₃, which does not contain A², may be referred to as “non-substituted perovskite compound FASnI₃”.

The lattice constant of the perovskite compound according to the present embodiment reflects a substitution ratio of A site with the organic compound (namely, A²) having a larger ionic radius than FA. In other words, the lattice constant of the perovskite compound according to the present embodiment reflects a mean ionic radius of the cation located at the A site. As above described, the perovskite compound according to the present embodiment has a larger lattice constant than a perovskite compound FASnI₃ which does not include A². This means that the organic compound (namely, A²) having a larger ionic radius than FA is located at the A site. If the lattice constant of the perovskite compound according to the present embodiment falls within the above range (i.e., more than 0.6315 nanometers and not more than 0.6363 nanometers), a short-circuit current density is prevented from being lowered.

In an X-ray diffraction pattern, an angle 2θ at which a cubical crystal (100) peak of the perovskite compound according to the present embodiment appears is smaller than an angle 2θ (=14.01°) at which a cubical crystal (100) peak of the perovskite compound FASnI₃ which does not include A² appears. The position where the cubical crystal (100) peak appears is provided on the basis of the result of the X-ray diffraction measurement (hereinafter, referred to as “XRD measurement”) using a CuKα ray. The photoabsorber according to the present embodiment may have a cubical crystal (100) peak which falls within the range of not less than 13.92° and less than 14.01° in the XRD measurement result using the CuKα ray.

The angle 2θ at which the cubical crystal (100) peak of the perovskite compound according to the present embodiment (namely, the position of the peak) reflects a substitution ratio of the A site with the organic compound (namely, A²) having a larger ionic radius than FA. In other words, the angle 2θ at which the cubical crystal (100) peak of the perovskite compound according to the present embodiment (namely, the position of the peak) reflects the mean ionic radius of the cation located at the A site. As above described, the angle 2θ at which the cubical crystal (100) peak of the perovskite compound according to the present embodiment (namely, the position of the peak) is smaller than the angle 2θ at which the cubical crystal (100) peak of the perovskite compound FASnI₃ which does not include A² appears. This means that the A site of the perovskite compound according to the present embodiment includes the organic compound (namely, A²) having a larger ionic radius than FA.

For the determination whether or not the A site includes the organic compound (namely, A²) having a larger ionic radius than FA, a (200) peak may be used as an index in place of the (100) peak of the perovskite compound. The photoabsorber according to the present embodiment may have a cubical crystal (200) peak which falls within the range of not less than 28.08° and less than 28.23° in the XRD measurement result using the CuKα ray. If the angle 2θ at which the cubical crystal (100) or (200) peak (namely, the position of the peak) appears falls within the above range, the short-circuit current density is prevented from being lowered.

When A² is EA, it is desirable that the following mathematical formula (Ia) is satisfied.

0.05≤[EA]/([FA]+[EA])≤0.6 (Ia)

where

[EA] is a molar number of EA, and

[FA] is a molar number of FA.

In other words, it is desirable that a molar ratio (=[EA]/([FA]+[EA])) of the molar number of EA to the sum of the molar numbers of [FA] and [EA] is not less than 0.05 and not more than 0.60. The molar ratio of not less than 0.05 and not more than 0.60 further improves the conversion efficiency of the perovskite solar cell comprising the photoabsorber according to the present embodiment. More desirably, the molar ratio (=[EA]/([FA]+[EA])) is not less than 0.05 and not more than 0.50. In other words, it is more desirable that the following mathematical formula (Ib) is satisfied.

0.05≤[EA]/([FA]+[EA])≤0.5 (Ib)

When A² is GA, it is desirable that the following mathematical formula (Ic) is satisfied.

0.091≤[GA]/([FA]+[GA])≤0.455 (Ic)

where

[GA] is a molar number of GA, and

[FA] is a molar number of FA.

In other words, it is desirable that a molar ratio (=[GA]/([FA]+[GA])) of the molar number of GA to the sum of the molar numbers of [FA] and [GA] is not less than 0.091 and not more than 0.455. The molar ratio of not less than 0.091 and not more than 0.455 further improves the conversion efficiency of the perovskite solar cell comprising the photoabsorber according to the present embodiment. More desirably, the molar ratio (=[GA]/([FA]+[GA])) is not less than 0.091 and not more than 0.364. In other words, it is more desirable that the following mathematical formula (Id) is satisfied.

0.091≤[GA]/([FA]+[GA])≤0.364 (Id)

Hereinafter, the fundamental function effect of the photoabsorber according to the present embodiment will be described.

(Properties of Perovskite Compound)

The photoabsorber according to the present embodiment can exhibit the following properties useful as a photoabsorber which is used for a solar cell.

The perovskite compound according to the present embodiment has a longer fluorescence lifetime than the conventional perovskite compound FASnI₃ which does not include A². For example, a single film provided by applying the perovskite compound according to the present embodiment in which the A site has been substituted with 9.1 at % of GA to a glass substrate has a fluorescence lifetime of 2.5 nanoseconds at 25 degrees Celsius. Hereinafter, a molar ratio of a molar number of GA to the sum of molar numbers of FA and GA is represented by a unit of at %. A single film provided by applying the perovskite compound according to the present embodiment in which the A site has been substituted with 18.2 at % of GA to a glass substrate has a fluorescence lifetime of 3.7 nanoseconds at the same condition. The conventional perovskite compound FASnI₃ which does not include A² has a fluorescence lifetime of 0.9 nanoseconds at the same condition.

The fluorescence lifetime of the perovskite compound is calculated, for example, on the basis of a fluorescence decay curve provided in the fluorescence lifetime measurement of the perovskite compound.

As above described, the present inventors believe that the binding between a 5s orbital of Sn and a 5p orbital of I is weakened when a part of the A site of the perovskite compound according to the present embodiment includes the organic compound (namely, A²) having a larger ionic radius than FA. As a result, compared to FASnI₃, the anti-bonding orbital is shifted to a lower energy side. For this reason, the present inventors believe that the number of Sn vacancies is decreased in the perovskite compound according to the present embodiment. As a result, the carrier recombination is prevented. In this way, the fluorescence lifetime of the perovskite compound is improved.

(Fabrication Method of Photoabsorber)

Hereinafter, a fabrication method of the perovskite compound according to the present embodiment will be described. A fabrication method of the perovskite compound according to the present embodiment is not limited. Now, a fabrication method by an inverse temperature crystallization method (hereinafter, referred to as “ITC method”) will be described.

First, SnI₂ and HC(NH₂)₂I (namely, FAI) are added to an organic solvent to prepare a mixture solution. The molar quantity of SnI₂ is equal to that of FAI. An example of the organic solvent is a mixture in which dimethylsulfoxide (namely, DMSO) and N,N-dimethylformamide (namely, DMF) have been mixed at volume ratio of 1:1.

Next, using a heating device such as a hot plate, the mixture solution is heated to a temperature which falls within a range of not less than 40 degrees Celsius and not more than 120 degrees Celsius to dissolve SnI₂ and FAI. In this way, a first solution is provided. Subsequently, the provided first solution is left at rest at room temperature.

Apart from the above, SnI₂, FAI, and C(NH₂)₃I (namely, GAI) are added to an organic solvent to provide a mixture solution. The molar concentration of SnI₂ may be not less than 0.8 mol/L and not more than 2.0 mol/L or may be not less than 0.8 mol/L and not more than 1.0 mol/L. The molar concentration of FAI may be not less than 0.4 mol/L and not more than 2.0 mol/L or may be not less than 0.4 mol/L and not more than 1.0 mol/L. The molar concentration of GAI may be more than 0 mol/L and not more than 1.0 mol/L or may be more than 0 mol/L and not more than 0.5 mol/L. An example of the organic solvent is y-valerolactone (hereinafter, referred to as “GVL”)

Next, using the heating device, the mixture solution is heated to a temperature which falls within a range of not less than 40 degrees Celsius and not more than 180 degrees Celsius to dissolve SnI₂, FAI, and GAI in the organic solvent. In this way, a second solution is provided. Subsequently, the provided second solution is left at rest at room temperature.

The first solution is applied to a glass substrate by a spin coat method. Then, the substrate is heated to a temperature which falls within a range of not less than 60 degrees Celsius and not more than 180 degrees Celsius. In this way, a template layer fo5rmed of FASnI₃ is formed on the glass substrate. When the spin coat method is employed, a drop of a poor solvent may be put onto the glass substrate during the spin coat. An example of the poor solvent is toluene, chlorobenzene, or diethyl ether.

Next, the second solution and the glass substrate on which the template layer has been formed are heated to a temperature which falls within a range of not less than 60 degrees Celsius and not more than 180 degrees Celsius. Subsequently, the second solution is applied to the template layer by a spin coat method, and then, the substrate is heated to a temperature which falls within a range of not less than 60 degrees Celsius and not more than 180 degrees Celsius. In other words, a drop of the second solution maintained at high temperature is put on the template layer maintained at high temperature. In this way, a crystal of FASnI₃ in which a part of FA located at the A site has been substituted with GA is grown on the template layer. After the spin coat, the grown crystal is subjected to heat treatment. In the heat treatment, the grown crystal may be heated at a temperature which falls within a range of not less than 40 degrees Celsius and not more than 100 degrees Celsius for not less than 15 minutes and not more than one hour. In this way, provided is the perovskite compound according to the present embodiment which has a property different from that of the template layer and in which a crystal orientation is reflected similarly to that of the template layer.

Hereinafter, a fabrication method of the perovskite compound according to the present embodiment using the spin coat by a method other than the ITC method will be described.

First, SnI₂, FAI, and GAI are added to an organic solvent to provide a mixture solution. An example of the organic solvent is a mixture in which dimethylsulfoxide (namely, DMSO) and N,N-dimethylformamide (namely, DMF) have been mixed at volume ratio of 1:1. The molar concentration of SnI₂ may be not less than 0.8 mol/L and not more than 2.0 mol/L or may be not less than 0.8 mol/L and not more than 1.0 mol/L. The molar concentration of FAI may be not less than 0.4 mol/L and not more than 2.0 mol/L or may be not less than 0.4 mol/L and not more than 1.0 mol/L. The molar concentration of GAI may be more than 0 mol/L and not more than 1.0 mol/L or may be more than 0 mol/L and not more than 0.5 mol/L.

Next, using the heating device, the mixture solution is heated to a temperature which falls within a range of not less than 40 degrees Celsius and not more than 180 degrees Celsius to dissolve SnI₂, FAI, and GAI in the organic solvent. In this way, a third solution is provided. Subsequently, the provided third solution is left at rest at room temperature.

Then, the third solution is applied to a glass substrate by a spin coat method. Then, the substrate is heated to a temperature which falls within a range of not less than 40 degrees Celsius and not more than 100 degrees Celsius for not less than 15 minutes and not more than one hour. In this way, the perovskite compound according to the present embodiment is provided. When the spin coat method is employed, a drop of a poor solvent may be put onto the substrate during the spin coat. An example of the poor solvent is toluene, chlorobenzene, or diethyl ether.

Each of the first-third solutions may contain a quencher material such as tin fluoride within a range of not less than 0.05 mol/L and not more than 0.4 mol/L. The quencher material prevents vacancies from being generated in the perovskite compound according to the present embodiment. The reason for the generation of the vacancies in the perovskite compound is, for example, (i) an increase in Sn vacancy or (ii) an increase in Se due to oxidation of Sn²⁺.

In the above-mentioned fabrication method, GA is selected as the organic compound having a larger ionic radius than FA; however, a similar effect is provided as long as the organic compound has a larger ionic radius than FA. Therefore, the organic compound having a larger ionic radius than FA is not limited to GA. An example of another organic compound having a larger ionic radius than FA is EA.

(Perovskite Solar Cell)

Hereinafter, the embodiment of the perovskite solar cell according to the present disclosure will be described.

The solar cell according to the present embodiment comprises a first electrode, a second electrode, a photoabsorber layer located between the first electrode and the second electrode. The first electrode faces the second electrode in such a manner that the photoabsorber is present between the first electrode and the second electrode. At least one electrode selected from the group consisting of the first electrode and the second electrode is light-transmissive. In the instant specification, the sentence “electrode is light-transmissive” means that not less than 10% of light having a wavelength of 200-2,000 nanometers travels through the electrode at a wavelength included therein. Since the solar cell according to the present embodiment includes the photoabsorber according to the present embodiment, the solar cell according to the present embodiment has high conversion efficiency. Hereinafter, seven structure examples of the solar cells (first example-seventh example) and the fabrication method thereof will be described with reference to the drawings.

(First Example of Solar Cell)

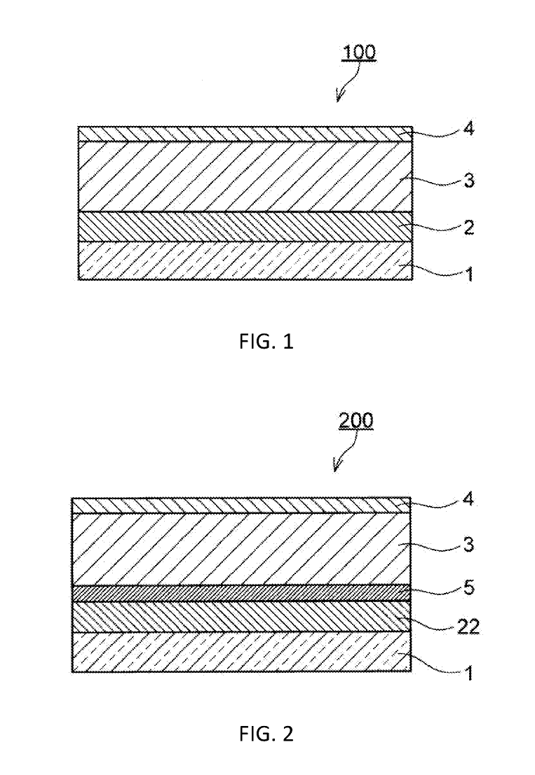

FIG. 1 is a cross-sectional view of the first example of the solar cell according to the present embodiment.

In a solar cell 100, a first electrode 2, a photoabsorber layer 3, and a second electrode 4 are stacked on a substrate 1 in this order. The photoabsorber layer 3 contains the photoabsorber formed of the perovskite compound according to the present embodiment. The solar cell 100 does not have to comprise the substrate 1.

Hereinafter, the fundamental function effect of the solar cell 100 will be described. When the solar cell 100 is irradiated with light, the light is absorbed into the photoabsorber layer 3. As a result, holes and excited electrons are generated in the photoabsorber layer 3. The excited electrons migrate to the first electrode 2. On the other hand, the holes generated in the photoabsorber layer 3 migrate to the second electrode 4. In this way, electric current is taken out from the first electrode 2 and the second electrode 4, which serve as a negative electrode and a positive electrode, respectively.

The solar cell 100 may be fabricated, for example, by the following method. First, the first electrode 2 is formed on the substrate 1 by a chemical vapor deposition method (hereinafter, referred to as a CVD method) or a sputtering method. Next, the photoabsorber layer 3 is formed on the first electrode 2 by the spin coat method, as above described. Subsequently, the second electrode 4 is formed on the photoabsorber layer 3. In this way, the solar cell 100 is provided.

Hereinafter, elements of the solar cell 100 will be described in more detail.

(Substrate 1)

The substrate 1 holds the layers of the solar cell 100. The substrate 1 may be formed of a transparent material. An example of the substrate 1 is a glass substrate or a plastic substrate. An example of the plastic substrate is a plastic film. When the first electrode 2 has sufficient strength, the photoabsorber layer 3 and the second electrode 4 can be stacked on or above the first electrode 2. Therefore, the solar cell 100 does not have to comprise the substrate 1.

(First Electrode 2)

The first electrode 2 has an electric conductivity. The first electrode 2 does not form an ohmic contact with the photoabsorber layer 3. Furthermore, the first electrode 2 has a hole block property that the holes migrating from the photoabsorber layer 3 are blocked. The hole block property is to allow only electrons generated in the photoabsorber layer 3 to travel through the first electrode 2 and to prevent holes generated in the photoabsorber layer 3 from traveling through the first electrode 2. The material having the hole block property is a material having a higher Fermi energy than the energy at the upper end of the valence band of the photoabsorber layer 3. The above material may have a higher Fermi energy than the photoabsorber layer 3. An example of a suitable material for the first electrode 2 required to have the hole block property is aluminum.

The first electrode 2 is light-transmissive. Light from visible light to near-infrared light passes through the first electrode 2. The first electrode 2 may be formed of a transparent and electrically-conductive metal oxide and/or nitride. An example of the material for the first electrode 2 is

(i) titanium oxide doped with at least one selected from the group consisting of lithium, magnesium, niobium, and fluorine;

(ii) gallium oxide doped with at least one selected from the group consisting of tin and silicon;

(iii) gallium nitride doped with at least one selected from the group consisting of silicon and oxygen;

(iv) indium-tin composite oxide; (v) tin oxide doped with at least one selected from the group consisting of antimony and fluorine;

(vi) zinc oxide doped with at least one selected from the group consisting of boron, aluminum, gallium, and indium; or

(vii) a composite thereof.

The first electrode 2 may be formed by providing a pattern through which light passes using a non-transparent material. An example of the pattern through which the light passes is a line (namely, a stripe), a wave, a grid (namely, a mesh), or a punching metal pattern on which a lot of fine through holes are arranged regularly or irregularly. When the first electrode 2 has the above-mentioned pattern, light can travel through a part in which an electrode material is absent. An example of the non-transparent material is platinum, gold, silver, copper, aluminum, rhodium, indium, titanium, iron, nickel, tin, zinc, or alloy containing at least two selected therefrom. An electrically-conductive carbon material may be used as the non-transparent material.

Light-transmissivity of the first electrode 2 is, for example, not less than 50%, or not less than 80%. A wavelength of the light which passes through the first electrode 2 is dependent on a wavelength of the light which is absorbed into the photoabsorber layer 3. The first electrode 2 has a thickness of, for example, not less than 1 nanometer and not more than 1,000 nanometers.

(Photoabsorber Layer 3)

The photoabsorber layer 3 contains the photoabsorber according to the present embodiment. In other words, the photoabsorber of the photoabsorber layer 3 includes the perovskite compound according to the present embodiment. The photoabsorber layer 3 has a thickness of, for example, not less than 100 nanometers and not more than 10 micrometers, which is dependent on the magnitude of light absorption of the photoabsorber layer 3. The photoabsorber layer 3 may have a thickness of not less than 100 nanometers and not more than 1,000 nanometers. The photoabsorber layer 3 may be formed by cutting a layer containing the perovskite compound. The photoabsorber layer 3 may have the template layer formed of FASnI₃ and the perovskite compound formed on the template layer.

(Second Electrode 4)

The second electrode 4 has electric conductivity. The second electrode 4 is not in ohmic contact with the photoabsorber layer 3. Furthermore, the second electrode 4 has an electron block property that the electrons migrating from the photoabsorber layer 3 are blocked. The electron block property is to allow only holes generated in the photoabsorber layer 3 to travel through the second electrode 4 and to prevent electrons generated in the photoabsorber layer 3 from traveling through the second electrode 4. The material having the electron block property is a material having a lower Fermi energy than the energy at the lower end of the conduction band of the photoabsorber layer 3. The above material may have a lower Fermi energy than the photoabsorber layer 3. An example of a suitable material for the second electrode 4 required to have the electron block property is platinum, gold, or a carbon material such as graphene.

(Second Example of Solar Cell)

FIG. 2 is a cross-sectional view of the second example of the solar cell according to the present embodiment. Unlike the solar cell 100 shown in FIG. 1, a solar cell 200 comprises an electron transport layer 5. The common referential signs are assigned to the elements each having the same function and configuration as that of the solar cell 100 and the description thereof will be approproiately omitted.

In the solar cell 200, a first electrode 22, the electron transport layer 5, the photoabsorber layer 3, and the second electrode 4 are stacked on the substrate 1 in this order. The solar cell 200 does not have to comprise the substrate 1.

Hereinafter, the fundamental function effect of the solar cell 200 will be described. When the solar cell 200 is irradiated with light, the light is absorbed into the photoabsorber layer 3. As a result, holes and excited electrons are generated in the photoabsorber layer 3. The excited electrons migrate through the electron transport layer 5 to the first electrode 22. On the other hand, the holes generated in the photoabsorber layer 3 migrate to the second electrode 4. In this way, electric current is taken out from the first electrode 22 and the second electrode 4, which serve as a negative electrode and a positive electrode, respectively.

Since the solar cell 200 is provided with the electron transport layer 5, the first electrode 22 does not have to have the hole block property that the holes migrating from the photoabsorber layer 3 are blocked. Therefore, the range of the choice of the material of the first electrode 22 is expanded.

The solar cell 200 may be fabricated in the same way as that of the solar cell 100 shown in FIG. 1. The electron transport layer 5 may be formed on the first electrode 22 by a sputtering method.

Hereinafter, elements of the solar cell 200 will be described in more detail.

(First Electrode 22)

The first electrode 22 has electric conductivity. The first electrode 22 may have the same configuration as the first electrode 2. Since the solar cell 200 comprises the electron transport layer 5, the first electrode 22 does not have to have the hole block property that the holes migrating from the photoabsorber layer 3 are blocked. In other words, the material of the first electrode 22 may be a material capable of being in ohmic contact with the photoabsorber layer 3.

The first electrode 22 is light-transmissive. Light from visible light to near-infrared light passes through the first electrode 22. The first electrode 22 may be formed of a transparent and electrically-conductive metal oxide and/or nitride. An example of the material for the first electrode 22 is

(i) titanium oxide doped with at least one selected from the group consisting of lithium, magnesium, niobium, and fluorine;

(ii) gallium oxide doped with at least one selected from the group consisting of tin and silicon;

(iii) gallium nitride doped with at least one selected from the group consisting of silicon and oxygen;

(iv) indium-tin composite oxide;

(v) tin oxide doped with at least one selected from the group consisting of antimony and fluorine;

(vi) zinc oxide doped with at least one selected from the group consisting of boron, aluminum, gallium, and indium; or (vii) a composite thereof.

The material of the first electrode 22 may be a non-transparent material. In this case, similarly to the case of the first electrode 2, the first electrode 22 is formed so as to have a pattern through which light travels. An example of the non-transparent material is platinum, gold, silver, copper, aluminum, rhodium, indium, titanium, iron, nickel, tin, zinc, or alloy containing at least two selected therefrom. An electrically-conductive carbon material may be used as the non-transparent material.

Light-transmissivity of the first electrode 22 is, for example, not less than 50%, or not less than 80%. A wavelength of the light which passes through the first electrode 22 is dependent on a wavelength of the light which is absorbed into the photoabsorber layer 3. The first electrode 22 has a thickness of, for example, not less than 1 nanometer and not more than 1,000 nanometers.

(Electron Transport Layer 5)

The electron transport layer 5 contains a semiconductor. The electron transport layer 5 may be formed of a semiconductor having a bandgap of not less than 3.0 eV. Visible light and infrared light travels through the electron transport layer 5 formed of the semiconductor having a bandgap of not less than 3.0 eV to reach the photoabsorber layer 3. An example of the semiconductor is an organic or inorganic n-type semiconductor.

An example of the organic n-type semiconductor is an imide compound, a quinone compound, fullerene, or a derivative of fullerene. An example of the inorganic n-type semiconductor is a metal oxide, a metal nitride, or a perovskite oxide. An example of the metal oxide is an oxide of Cd, Zn, In, Pb, Mo, W, Sb, Bi, Cu, Hg, Ti, Ag, Mn, Fe, V, Sn, Zr, Sr, Ga, Si, or Cr. TiO₂ is desirable. An example of the metal nitride is GaN. An example of the perovskite oxide is SrTiO₃ or CaTiO₃.

The electron transport layer 5 may be formed of a material having a bandgap of more than 6.0 eV. An example of the material having a bandgap of more than 6.0 eV is a halide of an alkali metal or alkali-earth metal (e.g., lithium fluoride or calcium fluoride), an alkali-earth metal oxide such as magnesium oxide, or silicon dioxide. In this case, to ensure the electron transport property of the electron transport layer 5, the electron transport layer 5 has a thickness of, for example, not more than 10 nanometers.

The electron transport layer 5 may include a plurality of layers each formed of a material different to each other.

(Third Example of Solar Cell)

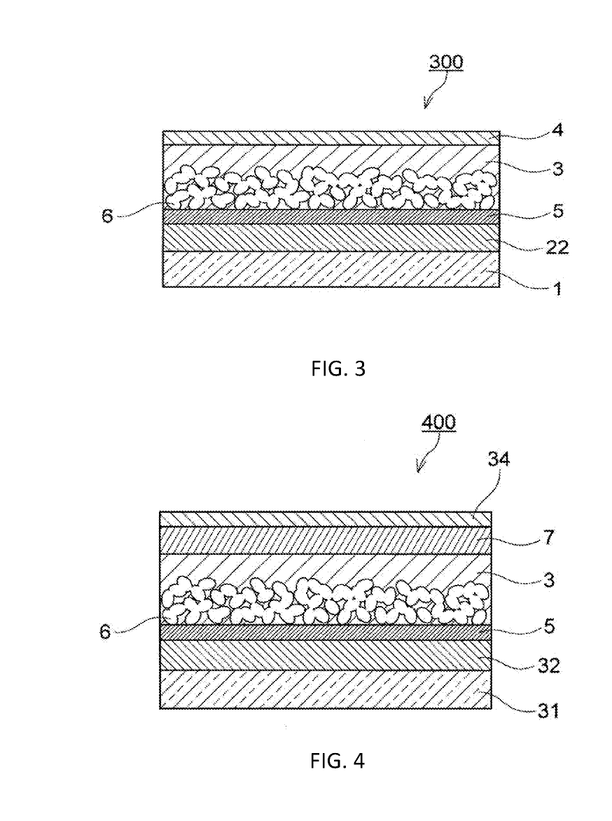

FIG. 3 is a cross-sectional view of the third example of the solar cell according to the present embodiment. Unlike the solar cell 200 shown in FIG. 2, a solar cell 300 comprises a porous layer 6. The common referential signs are assigned to the elements each having the same function and configuration as that of the solar cell 200 and the description thereof will be appropriately omitted.

In the solar cell 300, the first electrode 22, the electron transport layer 5, the porous layer 6, the photoabsorber layer 3, and the second electrode 4 are stacked on the substrate 1 in this order. The porous layer 6 contains a porous material. The porous material includes a pore. The solar cell 300 does not have to comprise the substrate 1.

The pore included in the porous layer 6 communicates from a part which is in contact with the photoabsorber layer 3 to a part which is in contact with the electron transport layer 5. The pore included in the porous layer 6 is filled with the material of the photoabsorber layer 3. The material of the photoabsorber layer 3 is in contact with the surface of the electron transport layer 5. Therefore, since the photoabsorber layer 3 is in contact with the electron transport layer 5, electrons migrate directly therebetween.

Hereinafter, the fundamental function effect of the solar cell 300 will be described. When the solar cell 300 is irradiated with light, the light is absorbed into the photoabsorber layer 3. As a result, holes and excited electrons are generated in the photoabsorber layer 3. The excited electrons migrate through the electron transport layer 5 to the first electrode 22. On the other hand, the holes generated in the photoabsorber layer 3 migrate to the second electrode 4. In this way, electric current is taken out from the first electrode 22 and the second electrode 4, which serve as a negative electrode and a positive electrode, respectively.

The porous layer 6 provided on the electron transport layer 5 facilitates the formation of the photoabsorber layer 3. In other words, the material of the photoabsorber layer 3 enters the pore included in the porous layer 6. In this way, the porous layer 6 becomes a foothold of the photoabsorber layer 3. So, the material of the photoabsorber layer 3 is hardly repelled or clumped on the surface of the porous layer 6. Therefore, the photoabsorber layer 3 can be formed as a uniform film.

(Porous Layer 6)

The porous layer 6 becomes a foothold of the formation of the photoabsorber layer 3. The porous layer 6 does not prevent the photoabsorber layer 3 from absorbing the light. In addition, the porous layer 6 does not prevent the electrons from migrating from the photoabsorber layer 3 to the electron transport layer 5. A length of light path of the light passing through the photoabsorber layer 3 is increased due to light scatter caused by the porous layer 6. It is believed that the amounts of the electrons and holes generated in the photoabsorber layer 3 are increased with increase in the length of the light path.

The porous layer 6 contains the porous material. An example of the porous material is a porous material in which insulative or semiconductor particles are connected. An example of the material of the insulative particles is aluminum oxide or silicon oxide. An example of the material of the semiconductor particles is an inorganic semiconductor. An example of the inorganic semiconductor is a metal oxide (including a perovskite oxide), a metal sulfide, or a metal chalcogenide. An example of the metal oxide is an oxide of Cd, Zn, In, Pb, Mo, W, Sb, Bi, Cu, Hg, Ti, Ag, Mn, Fe, V, Sn, Zr, Sr, Ga, Si, or Cr. TiO₂ is desirable. An example of the perovskite oxide is SrTiO₃ or CaTiO₃. An example of the metal sulfide is CdS, ZnS, In₂S₃, SnS, PbS, Mo₂S, WS₂, Sb₂S₃, Bi₂S₃, ZnCdS₂, or Cu₂S. An example of the metal chalcogenide is CdSe, CsSe, In₂Se₃, WSe₂, HgS, SnSe, PbSe, or CdTe.

The porous layer 6 may have a thickness of not less than not less than 0.1 micrometer and not more than 10 micrometers, or not less than not less than 0.1 micrometer and not more than 1 micrometer. The porous layer 6 may have a large surface roughness. In particular, surface roughness coefficient defined by a value of an effective area/a projected area may be not less than 10, or not less than 100. The effective area is an actual area of a surface of an object. The projected area is an area of a shadow of an object formed posteriorly to the object when light travelling from the front of the object is incident on the object. The effective area can be calculated from a volume calculated from the projected area and the thickness of the object, a specific surface area of the material which constitutes the object, and a bulk density of the object. The specific surface area is measured, for example, by a nitrogen adsorption method.

The solar cell 300 may be fabricated in the same way as that of the solar cell 200. The porous layer 6 is formed on the electron transport layer 5, for example, by a coating method.

The photoabsorber layer 3 is formed as below. A template layer formed of FASnI₃ is formed on the porous layer 6. A stacking structure including the photoabsorber layer 3 and the porous layer 6 is heated to high temperature. Then, a solution heated to the high temperature is applied by a spin coat method to the porous layer 6. Finally, a crystal of the perovskite compound is grown in the solution to form the photoabsorber layer 3. The formation method for the templete layer and the crystal growth method are not limited to the above. Another method (e.g., a spin coat method using the third solution, which has been described above) may be employed.

(Fourth Example of Solar Cell)

FIG. 4 is a cross-sectional view of the fourth example of the solar cell according to the present embodiment. Unlike the solar cell 300 shown in FIG. 3, a solar cell 400 comprises a hole transport layer 7. The common referential signs are assigned to the elements each having the same function and configuration as that of the solar cell 300 and the description thereof will be appropriately omitted.

In the solar cell 400, the first electrode 32, the electron transport layer 5, the porous layer 6, the photoabsorber layer 3, the hole transport layer 7, and the second electrode 34 are stacked on a substrate 31 in this order. The solar cell 400 does not have to comprise the substrate 31.

Hereinafter, the fundamental function effect of the solar cell 400 will be described.

When the solar cell 400 is irradiated with light, the light is absorbed into the photoabsorber layer 3. As a result, holes and excited electrons are generated in the photoabsorber layer 3. The excited electrons migrate to the electron transport layer 5. On the other hand, the holes generated in the photoabsorber layer 3 migrate to the hole transport layer 7. The electron transport layer 5 and the hole transport layer 7 are electrically connected to the first electrode 32 and the second electrode 34, respectively. In this way, electric current is taken out from the first electrode 32 and the second electrode 34, which serves as a negative electrode and a positive electrode, respectively in the solar cell 400.

Since the solar cell 400 is provided with the hole transport layer 7 which is present between the photoabsorber layer 3 and the second electrode 34, the second electrode 34 does not have to have the electron block property that the electrons migrating from the photoabsorber layer 3 are blocked. Therefore, the range of the choice of the material of the second electrode 34 is expanded.

Hereinafter, elements of the solar cell 400 will be described. The description of the elements common to those of the solar cell 300 will be omitted.

(First Electrode 32 and Second Electrode 34)

As above described, the second electrode 34 does not have to have the electron block property that the electrons migrating from the photoabsorber layer 3 are blocked. In other words, a material of the second electrode 34 may be a material capable of being in contact with the photoabsorber layer 3. Therefore, the second electrode 34 can be formed so as to be light-transmissive.

At least one electrode selected from the group consisting of the first electrode 32 and the second electrode 34 is light-transmissive and configured in the same way as the first electrode 2 of the solar cell 100.

At least one electrode selected from the group consisting of the first electrode 32 and the second electrode 34 does not have to be light-transmissive. In other words, a light-transmissive material is not necessarily used. The at least one electrode does not have to have a pattern including an opening part through which light travels.

(Substrate 31)

The substrate 31 may have the same configuration as the substrate 1 of the solar cell 100 shown in FIG. 1. When the second electrode 34 is light-transmissive, the substrate 31 does not have to be light-transmissive. An example of the substrate 31 is a metal, a ceramic, or a resin material having a small light-transmissivity.

(Hole Transport Layer 7)

The hole transport layer 7 is composed of an organic substance or an inorganic semiconductor. The hole transport layer 7 may have a plurality of layers each composed of a material different from each other.

In light of low resistance, it is desirable that the hole transport layer 7 has a thickness of not less than 1 nanometer and not more than 1,000 nanometers, more desirably, not less than 10 nanometers and not more than 50 nanometers. Within this range, the hole transport property is provided sufficiently to generate electric power with high efficiency.

As a formation method of the hole transport layer 7, a coating method or a printing method can be employed. An example of the coating method is a doctor blade method, a bar coating method, a spraying method, a dip coating method, or a spin coat method. An example of the printing method is a screen printing method. If necessary, the hole transport layer 7 is provided by forming a film using a mixture of plural materials, and then, applying a pressure to the film or sintering the film. When the material of the hole transport layer 7 is an organic low-molecular material or an inorganic semiconductor, the hole transport layer 7 may be formed by a vacuum evaporation method.

The hole transport layer 7 may contain a supporting electrolyte and a solvent. The supporting electrolyte and the solvent stabilize the holes included in the hole transport layer 7.

An example of the supporting electrolyte is an ammonium salt or an alkali metal salt. An example of the ammonium salt is tetrabutylammonium perchlorate, tetraethylammonium hexafluorophosphate, an imidazolium salt, or a pyridinium salt. An example of the alkali metal salt is lithium perchlorate or potassium tetrafluoroborate.

The solvent contained in the hole transport layer 7 may have high ionic conductivity. As the solvent, both an aqueous solvent and an organic solvent may be used. In view of more stabilization of the solute, the organic solvent is desirable. An example of the organic solvent is a heterocyclic compound solvent such as tert-butylpyridine, pyridine, or n-methylpyrrolidone.

As the solvent, an ionic liquid may be used solely. Alternatively, as the solvent, a mixture of an ionic liquid and another solvent may be used. The ionic liquid is desirable in view of its low volatility and high fire retardancy.

An example of the ionic liquid is an imidazolium-type ionic liquid such as 1-ethyl-3-methylimidazolium tetracyanoborate, a pyridine-type ionic liquid, an alicyclic amine-type ionic liquid, an aliphatic amine-type ionic liquid, or an azonium amine-type ionic liquid.

(Fifth Example of Solar Cell)

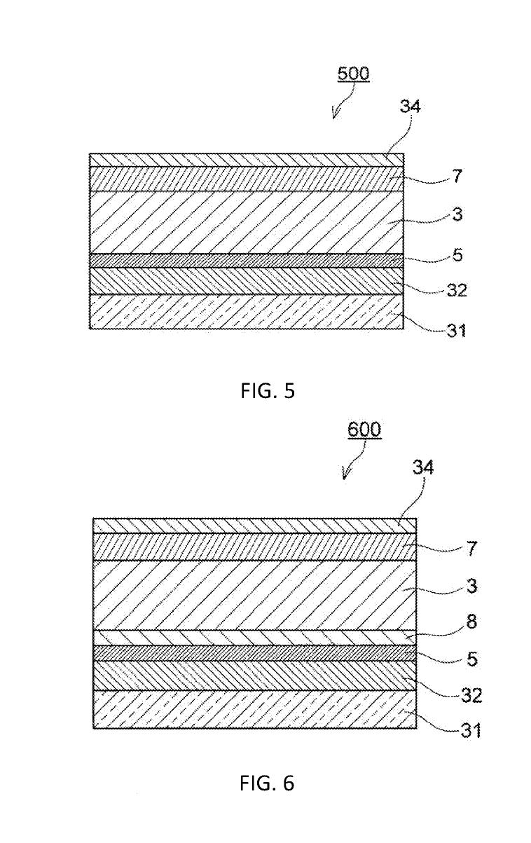

FIG. 5 is a cross-sectional view of the fifth example of the solar cell according to the present embodiment. Unlike the solar cell 400 shown in FIG. 4, a solar cell 500 does not comprise the porous layer 6. The common referential signs are assigned to the elements each having the same function and configuration as that of the solar cell 400 and the description thereof will be appropriately omitted.

In the solar cell 500, the first electrode 32, the electron transport layer 5, the photoabsorber layer 3, the hole transport layer 7, and the second electrode 34 are stacked on the substrate 31 in this order. The solar cell 500 does not have to comprise the substrate 31.

Hereinafter, the fundamental function effect of the solar cell 500 will be described.

When the solar cell 500 is irradiated with light, the light is absorbed into the photoabsorber layer 3. As a result, holes and excited electrons are generated in the photoabsorber layer 3. The excited electrons migrate to the electron transport layer 5. On the other hand, the holes generated in the photoabsorber layer 3 migrate to the hole transport layer 7. The electron transport layer 5 and the hole transport layer 7 are electrically connected to the first electrode 32 and the second electrode 34, respectively. In this way, electric current is taken out from the first electrode 32 and the second electrode 34 which serve as a negative electrode and a positive electrode, respectively.

(Sixth Example of Solar Cell)

FIG. 6 is a cross-sectional view of the sixth example of the solar cell according to the present embodiment. Unlike the solar cell 500 shown in FIG. 5, a solar cell 600 comprises a template layer 8. In the solar cell 600, the template layer 8 and the photoabsorber layer 3 may serve as the photoabsorber layer. In other words, the photoabsorber layer comprises the template layer 8 (hereinafter, which may be referred to as “first layer”) and the photoabsorber layer 3 (hereinafter, which may be referred to as “second layer”). The common referential signs are assigned to the elements each having the same function and configuration as that of the solar cell 500 and the description thereof will be appropriately omitted.

In the solar cell 600, the first electrode 32, the electron transport layer 5, the template layer 8, the photoabsorber layer 3, the hole transport layer 7, and the second electrode 34 are stacked on the substrate 31 in this order. The solar cell 600 does not have to comprise the substrate 31.

Hereinafter, the fundamental function effect of the solar cell 600 will be described.

When the solar cell 600 is irradiated with light, the light is absorbed into the photoabsorber layer 3. As a result, holes and excited electrons are generated in the photoabsorber layer 3. The excited electrons migrate to the template layer 8. The electrons which have migrated to the template layer 8 further migrate to the electron transport layer 5. On the other hand, the holes generated in the photoabsorber layer 3 migrate to the hole transport layer 7. The electron transport layer 5 and the hole transport layer 7 are electrically connected to the first electrode 32 and the second electrode 34, respectively. In this way, electric current is taken out from the first electrode 32 and the second electrode 34, which serve as a negative electrode and a positive electrode, respectively.

Hereinafter, elements of the solar cell 600 will be described. The description of the elements common to those of the solar cell 500 will be appropriately omitted.

(Template Layer 8)

The template layer 8 contains a perovskite compound which is represented by the composition formula ABX₃ (where, A is a monovalent cation, B is a divalent cation, and X is a halogen anion) and has a perovskite structure. The perovskite compound contained in the template layer 8 is, for example, FASnI₃. The perovskite compound contained in the template layer 8 may have different composition from that of the perovskite compound according to the present embodiment. The template layer 8 has a thickness of, for example, not less than 50 nanometers and not more than 1,000 nanometers.

The template layer 8 is formed on the electron transport layer 5. The template layer 8 may be formed by the method described in the section of the fabrication method of the photoabsorber layer 3. The photoabsorber layer 3 may be formed by the fabrication method described in the third example.

(Seventh Example of Solar Cell)

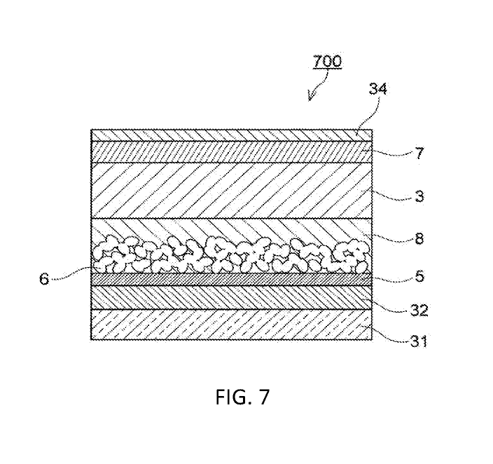

FIG. 7 is a cross-sectional view of the seventh example of the solar cell according to the present embodiment. Unlike the solar cell 600 shown in FIG. 6, a solar cell 700 comprises the porous layer 6. The common referential signs are assigned to the elements each having the same function and configuration as that of the solar cell 600 and the description thereof will be appropriately omitted.

In the solar cell 700, the first electrode 32, the electron transport layer 5, the porous layer 6, the template layer 8, the photoabsorber layer 3, the hole transport layer 7, and the second electrode 34 are stacked on the substrate 31 in this order. The porous layer 6 contains the porous material. The porous material includes a pore. The solar cell 700 does not have to comprise the substrate 31.

The pore included in the porous layer 6 communicates from a part which is in contact with the template layer 8 to a part which is in contact with the electron transport layer 5. The pore included in the porous layer 6 is filled with the material of the template layer 8. The material of the template layer 8 is in contact with the surface of the electron transport layer 5. Therefore, since the template layer 8 is in contact with the electron transport layer 5, electrons migrate directly therebetween.

Hereinafter, the fundamental function effect of the solar cell 700 will be described. When the solar cell 700 is irradiated with light, the light is absorbed into the photoabsorber layer 3. As a result, holes and excited electrons are generated in the photoabsorber layer 3. The excited electrons migrate to the template layer 8. The electrons which have migrated to the template layer 8 further migrate to the electron transport layer 5. On the other hand, the holes generated in the photoabsorber layer 3 migrate to the hole transport layer 7. The electron transport layer 5 and the hole transport layer 7 are electrically connected to the first electrode 32 and the second electrode 34, respectively. In this way, electric current is taken out from the first electrode 32 and the second electrode 34 which serve as a negative electrode and a positive electrode, respectively.

The porous layer 6 provided on the electron transport layer 5 facilitates the formation of the template layer 8. This is the same as the effect that the porous layer 6 facilitates the formation of the photoabsorber layer 3, as described in the section of the third example of the solar cell.

### EXAMPLES

The present disclosure will be described in more detail with reference to the following examples. In the following inventive examples and comparative examples, perovskite compounds were prepared. The crystal structures of the prepared perovskite compounds were analyzed with an XRD measurement. On the basis of the analysis results, lattice constants of the perovskite compounds were calculated. Furthermore, properties of the solar cells provided using the perovskite compounds were evaluated.

### PREPARATION OF COMPOUNDS IN INVENTIVE AND COMPARATIVE EXAMPLES

### Inventive Examples 1-7

First, a solution containing SnI₂, FAI, EAI, and SnF₂ having the following concentrations were added to a mixture solvent of dimethylsulfoxide (namely, DMSO) and N,N-dimethylformamide (namely, DMF) (volume ratio 1:1) to prepare a mixture solution.

SnI₂: 1 mol/L

SnF₂: 0.1 mol/L

Sum of concentrations of FAI and EAI (=[FA]+[EA]): 1 mol/L

Concentrations of EAI (=[EA]) in the inventive examples 1-7: 0.05 mol/L, 0.10 mol/L, 0.15 mol/L, 0.20 mol/L, 0.30 mol/L, 0.40 mol/L, and 0.50 mol/L, respectively.

The ratio of concentrations (=[EA]/([FA]+[EA])) is equal to the substitution ratio of EA in the A site of the prepared perovskite compound. For example, when the ratio of concentrations is 5.0%, the substitution ratio of EA is 5.0 at %, and the prepared perovskite compound has a composition formula of FA_{0.95}EA_{0.05}SnI₃.

Next, the mixture solution is applied to a substrate by a spin coat method. During the application, a drop of chlorobenzene (200 microliters) was put on the rotating substrate. The substrate was a glass substrate having a thickness of 0.7 millimeters. Then, the substrate was heated on a hot plate at 65 degrees Celsius for twenty minutes to prepare the perovskite compound FA₁₋ₓEAₓSnI₃ films of the inventive examples 1-7 (x=0.05, 0.10, 0.15, 0.20, 0.30, 0.40, and 0.50, respectively). In other words, in the photoabsorbers of the inventive examples 1-7, a molar ratio of the molar number of the ethylammonium cations to the sum of the molar numbers of the formamidinium cations and the ethylammonium cations was 5.0%, 10.0%, 15.0%, 20.0%, 30.0%, 40.0%, and 50.0%, respectively.

### Inventive Examples 8-14

The solar cells of the inventive examples 8-14 were fabricated by a method which will be described later. The solar cells of the inventive examples 8-14 had the same structure as the solar cell 400 (see FIG. 4) described in the above-mentioned section of the fourth example. The details of the solar cells of the inventive examples 8-14 will be described below.

Substrate 31: Glass substrate (thickness: 0.7 millimeters)

First electrode 32: Indium-tin composite oxide transparent electrode (thickness: 100 nanometers)

Electron transport layer 5: Titanium oxide

Porous layer 6: Titanium oxide having a mesoporous structure

Photoabsorber layer 3 in the inventive examples 8-14: FA_{1—},EAₓSnI₃ (x=0.05, 0.10, 0.15, 0.20, 0.30, 0.40, and 0.50, respectively) (thickness: 300 nanometers)

Hole transport layer 7: Polytriallylamine (hereinafter, referred to as “PTAH”)

Second electrode 34: Au (thickness: 100 nanometers)

The solar cells of the inventive examples 8 -14 were fabricated as below.

First, a substrate 31 having a transparent conductive layer on the surface thereof was prepared. The transparent conductive layer served as a first electrode 32. In the present inventive examples, the substrate 31 was a glass substrate having a thickness of 0.7 millimeters. The first electrode 32 was an indium-tin composite oxide film. The electron transport layer 5 was a titanium oxide layer. The porous layer 6 was formed of titanium oxide having a mesoporous structure.

Next, a solution containinig SnI₂, FAI, EAI, and SnF₂ having the following concentrations were added to a mixture solvent of dimethylsulfoxide (namely, DMSO) and N,N-dimethylformamide (namely, DMF) (volume ratio 1:1) to prepare a mixture solution.

SnI₂: 1 mol/L

SnF₂: 0.1 mol/L

Sum of concentrations of FAI and EAI (=[FA]+[EA]): 1 mol/L Concentrations of EAI (=[EA]) in the inventive examples 8-14: 0.05 mol/L,

0.10 mol/L, 0.15 mol/L, 0.20 mol/L, 0.30 mol/L, 0.40 mol/L, and 0.50 mol/L, respectively.

Next, the mixture solution is applied to the first electrode 32 by a spin coat method. During the application, a drop of chlorobenzene (200 microliters) was put on the rotating substrate 31. Then, the substrate was heated on a hot plate at 65 degrees Celsius for twenty minutes to provide seven samples in each of which the photoabsorber layer 3 formed of the perovskite compound FA₁₋ₓEA_{c}SnI₃ (x=0.05, 0.10, 0.15, 0.20, 0.30, 0.40, and 0.50, in the inventive examples 8-14, respectively) were formed on the porous layer 6. In other words, in the photoabsorbers included in the solar cells of the inventive examples 8-14, a molar ratio of the molar number of the ethylammonium cations to the sum of the molar numbers of the formamidinium cations and the ethylammonium cations was 5.0%, 10.0%, 15.0%, 20.0%, 30.0%, 40.0%, and 50.0%, respectively.

Subsequently, PTAA (10 milligrams) was dissolved in toluene (1 milliliter) to prepare a toluene solution. Then, the toluene solution was applied by a spin coat method to form the hole transport layer 7 on the photoabsorber layer 3.

Then, an Au film having a thickness of 100 nanometers was deposited on the hole transport layer 7 by a vacuum evaporation method to form the second electrode 34. In this way, the solar cells of the inventive examples 8-14 were fabricated.

### Inventive Examples 15-17

First, a solution containinig SnI₂ and FAI were added to a mixture solvent of dimethylsulfoxide (namely, DMSO) and N,N-dimethylformamide (namely, DMF) (volume ratio 1:1) to prepare a mixture solution.

SnI₂: 1 mol/L

FAI: 0.1 mol/L

Next, the mixture solution was applied to a substrate by a spin coat method. During the application, a drop of chlorobenzene (200 microliters) was put on the rotating substrate. The substrate was a glass substrate having a thickness of 0.7 millimeters. Then, the substrate was heated on a hot plate at 100 degrees Celsius for fifteen minutes to provide a template layer.

Subsequently, a GVL solution containing SnI₂, FAI, GAI, and SnF₂ having the following concentrations was prepared.

SnI₂: 1 mol/L

Sum of concentrations of FAI and GAI (=[FA]+[GA]): 1.1 mol/L

In the inventive examples 15-17, a ratio of the concentration of GAI to the sum of the concentrations of FAI and GAI (=[GA]/[FA]+[GA])) was 9.1%, 18.2%, and 27.3%, respectively.

The ratio of concentrations (=[GA]/([FA]+[GA])) is equal to the substitution ratio of GA in the A site of the prepared perovskite compound. For example, when the ratio of concentrations is 9.1%, the substitution ratio of GA is 9.1 at %, and the prepared perovskite compound has a composition formula of FA_{0.909}GA_{0.091}SnI₃.

Then, the GVL solution was heated to 140 degrees Celsius. The substrate comprising the template layer was also heated to 140 degrees Celsius. The GVL solution was applied to the template layer by a spin coat method, and then, a crystal was grown in the GVL solution. Subsequently, the substrate was heated on a hot plate at 100 degrees Celsius for 10 minutes, and then, the substrate was heated on the hot plate at 180 degrees Celsius for 15 minutes. In this way, perovskite compound FA₁₋ₓGAₓSnI₃ films of the inventive examples 15-17 were provided (x=0.091, 0.182, and 0.273, in the inventive examples 15-17, respectively) as the photoabsorber layers 3. In other words, in the photoabsorbers in the inventive examples 15-17, a molar ratio of the molar number of the guanidinium cations to the sum of the molar numbers of the formamidinium cations and the guanidinium cations was 9.1%, 18.2%, and 27.3%, respectively.

### Inventive Examples 18-21

The solar cells of the inventive examples 18-21 were fabricated by a method which will be described later. In the solar cells of the inventive examples 18-21 had the same structure as the solar cell 700 (see FIG. 7) described in the above-mentioned section of the seventh example. The details of the solar cells of the inventive examples 18-21 will be described below.

Substrate 31: Glass substrate (thickness: 0.7 millimeters)

First electrode 32: Transparent electrode of an indium-tin composite oxide layer (thickness: 100 nanometers) and a tin oxide layer doped with antimony (thickness: 100 nanometers)

Electron transport layer 5: Titanium oxide

Porous layer 6: Titanium oxide having a mesoporous structure

Template layer 8: FASnI₃

Photoabsorber layer 3 in the inventive examples 18-21: FA₁₋ₓGAₓSnI₃ (x=0.091, 0.182, 0.273, and 0.364, respectively) (thickness: 1,000 nanometers)

Hole transport layer 7: Polytriallylamine (hereinafter, referred to as “PTAA”)

Second electrode 34: Au (thickness: 100 nanometers)

The solar cells of the inventive examples 18-21 were fabricated as below.

First, a substrate 31 having a transparent conductive layer on the surface thereof was prepared. The transparent conductive layer served as a first electrode 32. In the present inventive examples, the substrate 31 was a glass substrate having a thickness of 0.7 millimeters. The first electrode 32 was a transparent electrode of an indium-tin composite oxide layer and a tin oxide layer doped with antimony. The indium-tin composite oxide layer of the first electrode 32 was present between the substrate 31 and the tin oxide layer doped with antimony of the first electrode 32. The electron transport layer 5 was a titanium oxide layer. The porous layer 6 was formed of titanium oxide having a mesoporous structure.

Next, a solution containing SnI₂ and FAI having the following concentrations was added to a mixture solvent of dimethylsulfoxide (namely, DMSO) and N,N-dimethylformamide (namely, DMF) (volume ratio 1:1) to prepare a mixture solution.

SnI₂: 1 mol/L

FAI: 0.1 mol/L

Next, the mixture solution is applied to the first electrode 32 by a spin coat method. During the application, a drop of chlorobenzene (200 microliters) was put on the rotating substrate. Then, the substrate was heated on a hot plate at 100 degrees Celsius for fifteen minutes to provide a template layer 8.

Subsequently, a GVL solution containing SnI₂, FAI, GAI, and SnF₂ having the following concentrations was prepared.

SnI₂: 1 mol/L

SnF₂: 0.1 mol/L

Sum of concentrations of FAI and GAI (=[FA]+[GA]): 1.1 mol/L In the inventive examples 18-21, a ratio of the concentration of GAI to the sum of the concentrations of FAI and GAI (=[GA]/[FA]+[GA])) was 9.1%, 18.2%, 27.3%, and 36.4%, respectively.

Then, the GVL solution was heated to 140 degrees Celsius. The substrate 31 comprising the template layer 8 was also heated to 140 degrees Celsius. The GVL solution was applied to the template layer 8 by a spin-coat method, and then, a crystal was grown in the GVL solution. Subsequently, the substrate 31 was heated on a hot plate at 100 degrees Celsius for 10 minutes, and then, the substrate was heated on the hot plate at 180 degrees Celsius for 15 minutes. In this way, perovskite compound FA₁₋ₓGAₓSnI₃ films of the inventive examples 18-21 were provided (x=0.091, 0.182, 0.273, and 0.364, in the inventive examples 18-21, respectively) as the photoabsorber layers 3. In other words, in the photoabsorbers included in the solar cells of the inventive examples 18-21, a molar ratio of the molar number of the guanidinium cations to the sum of the molar numbers of the formamidinium cations and guanidinium cations was 9.1%, 18.2%, 27.3%, and 36.4%, respectively.

Subsequently, PTAA (10 milligrams) was dissolved in toluene (1 milliliter) to prepare a toluene solution. Then, the toluene solution was applied by a spin coat method to form the hole transport layer 7 on the photoabsorber layer 3.

Then, an Au film having a thickness of 100 nanometers was deposited on the hole transport layer 7 by a vacuum evaporation method to form the second electrode 34. In this way, the solar cells of the inventive examples 18-21 were fabricated.

### Comparative Example 1

In the comparative example 1, the perovskite compound film was formed similarly to the inventive example 1, except that the mixture solution did not contain EAI. The perovskite compound film formed in the comparative example 1 was a FASnI₃ film.

### Comparative Example 2

In the comparative example 2, the solar cell 400 shown in FIG. 4 was fabricated similarly to the inventive example 8, except that the mixture solution did not contain EAI. The photoabsorber layer 3 included in the solar cell 400 of the comparative example 2 was a perovskite compound FASnI₃ film.

### Comparative Example 3

In the comparative example 3, the perovskite compound film was formed similarly to the inventive example 15, except that the GVL solution did not contain GAI. The perovskite compound film formed in the comparative example 3 was a FASnI₃ film.

### Comparative Example 4

In the comparative example 4, the solar cell 700 shown in FIG. 7 was fabricated similarly to the inventive example 15, except that the GVL solution did not contain GAI. The photoabsorber layer 3 included in the solar cell 700 of the comparative example 4 was a perovskite compound FASnI₃ film.

### Comparative Example 5

In the comparative example 5, the compound was prepared similarly to the inventive example 15, except that the GVL solution contained GAI in place of FAI. The compound prepared in the comparative example 5 was GASnI₃.

(Crystal Structure Analysis)

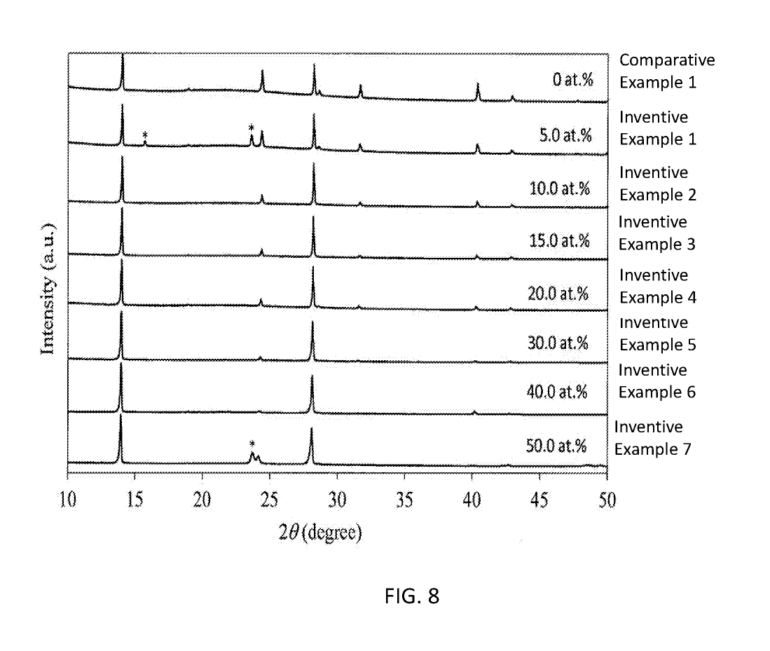

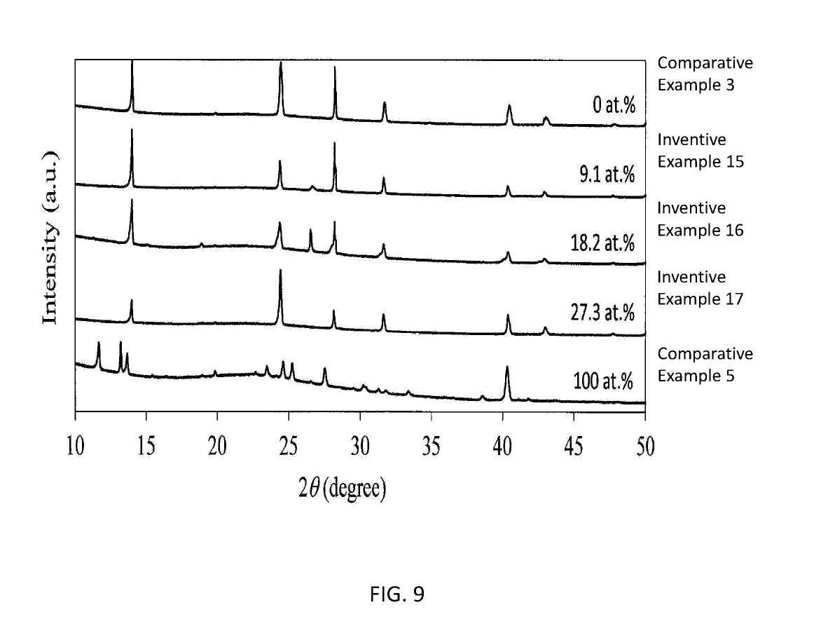

The compounds prepared in the inventive examples 1-7 and 15-17 and the comparative examples 1, 3, and 5 were subjected to an XRD measurement using a CuKα ray. FIG. 8 is a graph showing the results of the XRD measurement of the compounds prepared in the inventive examples 1-7 and the comparative example 1. FIG. 9 is a graph showing the results of the XRD measurement of the compounds prepared in the inventive examples 15-17 and the comparative examples 3 and 5. In FIG. 8 and FIG. 9, the horizontal axis and the vertical axis indicate a diffraction angle 2θ and an X-ray diffraction intensity, respectively.

As is clear from FIG. 8 and FIG. 9, each of the compounds prepared in the inventive examples 1-7 and 15-17 and the comparative examples 1 and 3 has a perovskite crystal structure, whereas the compound prepared in the comparative example 5 does not have a perovskite crystal structure. In the measurement result of the compound prepared in the comparative example 5, hexagonal crystal GASnI₃ peaks appear. In particular, peaks appear at diffraction angles 2θ of 11.7°, 13.2°, 13.7°, 23.5°, 24.6°, 25.2°, and 27.5°.

Similarly to the disclosure in Non-Patent Literature 3, all of the diffraction peaks of the perovskite compounds prepared in the inventive examples 1-7 and 15-17 were verified as a cubic phase (pm-3m, No. 221). Among the inventive examples 1-7, only in the inventive examples 1 and 7, the peaks appear in the vicinity of the diffraction angles 2θ of 15.7° and 23.6° (See asterisks in FIG. 8). It appears that these peaks are derived from impurities. However, each of the perovskite compounds prepared in the inventive examples 1-7 has a single phase. In the perovskite compounds prepared in the inventive examples 15-17, no peaks derived from GAI, which is one of the starting materials, are observed. In addition, no peaks derived from hexagonal crystal GASnI₃ are observed. This means that each of the perovskite compounds prepared in the inventive examples 15-17 has no impurity phase. The diffraction peaks of GAI, which is one of the starting materials, appear at diffraction angles 2θ of 14.9°, 37.8°, and 43.7°. Only in the inventive examples 15 and 16, a peak appears in the vicinity of a diffraction angle 2θ of 26.5° . This peak would be derived from trigonal FASnI₃ having a high orientation.

(Lattice Constant Change)

The perovskite compounds contained in the photoabsorber layers of the solar cells fabricated in the inventive examples 8-14 and the comparative example 2 are the substantially same as the perovskite compounds prepared in the inventive examples 1-7 and the comparative example 1, respectively.

The following Table 1 shows a lattice constant and a diffraction angle 2θ of the position of the cubical crystal (100) peak of the perovskite compound included in the photoabsorber layers of the solar cells fabricated in the inventive examples 8-14 and the comparative example 2. In the following Tables, “C.E.” and “I.E.” mean “comparative example” and “inventive example”, respectively.

TABLE 1

| | Substitution | | | Diffraction Angle |
|---|---|---|---|---|
| | Ratio | Mean Ionic | Lattice | 2θ of Position |
| | (=([EA])/ | Radius | Constant | of Cubical Crystal |
| | ([FA] + [EA])) | (nanometers) | (nanometers) | (100) Peak (°) |
| C.E. 2 | 0% | 253 | 0.6314 | 14.01 |
| I.E. 8 | 5.0% | 254 | 0.6320 | 14.00 |
| I.E. 9 | 10.0% | 255 | 0.6320 | 14.00 |
| I.E. 10 | 15.0% | 256 | 0.6325 | 13.98 |
| I.E. 11 | 20.0% | 257 | 0.6335 | 13.97 |
| I.E. 12 | 30.0% | 259 | 0.6344 | 13.95 |
| I.E. 13 | 40.0% | 261 | 0.6349 | 13.94 |
| I.E. 14 | 50.0% | 265 | 0.6363 | 13.92 |

The perovskite compounds contained in the photoabsorber layers of the solar cells fabricated in the inventive examples 18-20 and the comparative example 4 are the substantially same as the perovskite compounds prepared in the inventive examples 15-17 and the comparative example 3, respectively.

The following Table 2 shows a lattice constant and a diffraction angle 2θ of the position of the cubical crystal (100) peak of the perovskite compound included in the photoabsorber layers of the solar cells fabricated in the inventive examples 18-21 and the comparative example 4.

TABLE 2

| | Substitution | | | Diffraction Angle |
|---|---|---|---|---|
| | Ratio | Mean Ionic | Lattice | 2θ of Position |
| | (=[GA])/ | Radius | Constant | of Cubical Crystal |
| | ([FA] + [GA])) | (nanometers) | (nanometers) | (100) Peak (°) |
| C.E. 4 | 0% | 253 | 0.6315 | 14.01 |
| I.E. 18 | 9.1% | 255 | 0.6321 | 13.99 |
| I.E. 19 | 18.2% | 258 | 0.6324 | 13.99 |
| I.E. 20 | 27.3% | 260 | 0.6338 | 13.97 |
| I.E. 21 | 36.4% | 262 | (0.6352) | (13.93) |

As is clear from Table 1 and Table 2, the lattice constant of the perovskite compound is increased with an increase in the substation amount with EA or GA. The diffraction angle 2θ of the position of the cubical crystal (100) peak is decreased with an increase in the substitution ratio (namely, the value of at. %) of the A site with the organic molecule ion having a larger mean ion radius than FA.

The mean ionic radius shown in Table 1 and Table 2 is a mean ionic radius of the ion located at the A site of the perovskite compound prepared in the inventive examples and the comparative examples. The mean ionic radius is calculated on the basis of the following mathematical formula (II).

(Mean Ionic Radius)=(Ionic Radius of EA or GA)·(Substitution Ratio)/100+(Ionic Radius of FA)·(1−(Substitution Ratio)/100) (II)

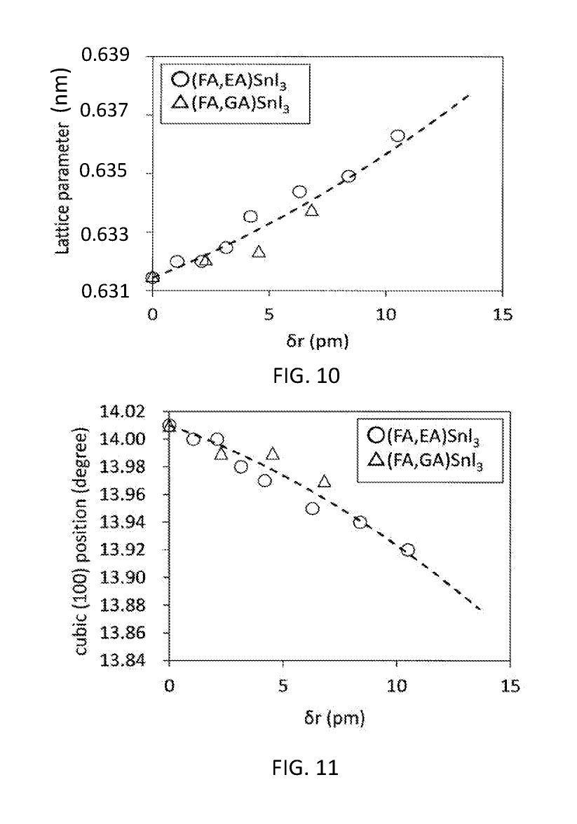

FIG. 10 is a graph showing a relation between a difference δr and the lattice constant in the inventive examples 8-20 and the comparative examples 2 and 4. The difference δr is calculated on the basis of the following mathematical formula (III).

(Difference δr)=(Mean ionic radius)−(Ionic radius of FA ion, namely, 0.253 nanometers) (III)

FIG. 11 is a graph showing a relation between the difference δr and the diffraction angle 2θ of the position of the cubical crystal (100) peak in the inventive examples 8-20 and the comparative examples 2 and 4.

Dashed lines included in FIG. 10 and FIG. 11 indicate fitting results. The lattice constant and the diffraction angle 2θ of the position of the cubical crystal (100) peak of the perovskite compound of the inventive example 21 was calculated on the basis of the fitting curve included in FIG. 10 and FIG. 11. In Table 2, parentheses have been added to the calculated lattice constant and diffraction angle 2θ.

(Solar Cell Properties)

The solar cell properties includes open voltage Voc, short-circuit current density Jsc, fill factor FF, and photoelectric conversion efficiency Eff. These properties are well known in the art of the solar cell, including the measurement and calculation method thereof.

Table 3 shows properties of the solar cells fabricated in the inventive examples 8-14 and the comparative example 2.

TABLE 3

| | Substitution | | | | |
|---|---|---|---|---|---|
| | Ratio | | | | |
| | (=([EA])/ | | Jsc | | |
| | ([FA] + [EA])) | Voc (V) | (mA/cm²) | FF | Eff (%) |
| C.E. 2 | 0% | 0.266 | 7.92 | 0.307 | 0.65 |
| I.E. 8 | 5.0% | 0.234 | 21.95 | 0.427 | 2.19 |
| I.E. 9 | 10.0% | 0.276 | 23.97 | 0.488 | 3.23 |
| I.E. 10 | 15.0% | 0.303 | 24.68 | 0.514 | 3.84 |
| I.E. 11 | 20.0% | 0.311 | 23.81 | 0.518 | 3.83 |
| I.E. 12 | 30.0% | 0.340 | 21.91 | 0.512 | 3.81 |
| I.E. 13 | 40.0% | 0.378 | 20.75 | 0.586 | 4.59 |
| I.E. 14 | 50.0% | 0.319 | 16.25 | 0.458 | 2.37 |

Table 4 shows properties of the solar cells fabricated in the inventive examples 18-21 and the comparative example 4.

TABLE 4

| | Substitution | | | | |
|---|---|---|---|---|---|
| | Ratio | | | | |
| | (=[GA])/ | | Jsc | | |
| | ([FA] + [GA])) | Voc (V) | (mA/cm²) | FF | Eff(%) |
| C.E. 4 | 0% | 0.200 | 7.15 | 0.421 | 0.60 |
| I.E. 18 | 9.1% | 0.255 | 7.45 | 0.431 | 0.82 |
| I.E. 19 | 18.2% | 0.202 | 9.92 | 0.399 | 0.80 |
| I.E. 20 | 27.3% | 0.223 | 6.41 | 0.430 | 0.62 |
| I.E. 21 | 36.4% | 0.213 | 8.28 | 0.388 | 0.68 |

As is clear from Table 3 and Table 4, the open voltage Voc of the solar cell tends to increase with an increase in the substitution ratio of EA at the A site. The present inventors believe that the open voltage Voc is increased due to an increase in the energy gap of the perovskite compound. In the comparative example 2 in which the perovskite compound having an EA substitution ratio of 0 at. % is prepared, the short-circuit current density Jsc is 7.92 mA/cm². On the other hand, in the inventive example 10 in which the perovskite compound having an EA substitution ratio of 15 at. % is prepared, the short-circuit current density Jsc is 24.68 mA/cm². In other words, the short-circuit current density Jsc is higher in the inventive example 10 than the comparative example 2, although the present inventors believe that the perovskite compound prepared in the inventive example 10 has a larger band gap than that of the comparative example 2. On the basis of the above, the present inventors believe that the number of the Sn vacancies included in the perovskite compound is decreased due to the substitution of FA with EA and that the possibility of the recombination of the carriers is lowered. In the comparative example 2 in which the perovskite compound having an EA substitution ratio of 0 at. % is prepared, the conversion efficiency Eff is 0.65%. On the other hand, in the inventive example 13 in which the perovskite compound having an EA substitution ratio of 40.0 at. % is prepared, the conversion efficiency Eff is 4.59%.

Similarly to the case where a part of the A site is substituted with EA, with an increase in the GA substitution ratio at the A site, the open voltage Voc and the short-circuit current density Jsc tend to increase. In the inventive example 19 in which the perovskite compound having an GA substitution ratio of 18.2 at. % is prepared, the short-circuit current density Jsc is maximum. The value thereof is 9.92 mA / cm². In the comparative example 4 in which the perovskite compound having an GA substitution ratio of 0 at. % is prepared, the conversion efficiency is 0.60%. On the other hand, in the inventive example 18 in which the perovskite compound having an GA substitution ratio of 9.1 at. % is prepared, the conversion efficiency is 0.82%.

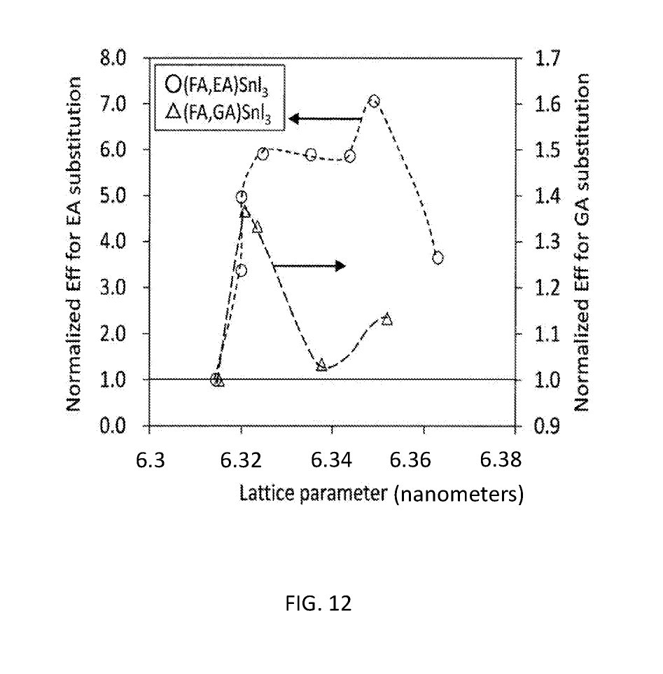

FIG. 12 is a graph showing a relation between the lattice constant of the perovskite compounds included in the photoabsorber layers of the solar cells fabricated in the inventive examples 8-14 and 18-21 and normalized conversion efficiency of the solar cells. The normalized conversion efficiency is calculated by normalizing the conversion efficiency of the solar cell which has the perovskite compound which includes EA or GA with the conversion efficiency of the solar cell which has the perovskite compound which does not include EA or GA. As understood from FIG. 12, in the lattice constant within the range of more than 0.6315 nanometers and not more than 0.6363 nanometers, the solar cells fabricated in the inventive examples 8-14 and 18-21 have a higher conversion efficiency than the solar cell including the perovskite compound which does not include EA or GA. As understood from FIG. 12, the normalized conversion efficiency is not less than 1. This means that the part of the A site is substituted with the organic compound having an ionic radius larger than the formamidinium cation to improve the conversion efficiency, compared to the conventional perovskite compound FASnI₃ (namely, non-substituted perovskite compound FASnI₃), which does not contain A², without depending on the kind of the organic compound with which the part of the A-site is substituted.

The results of the above examples reveal that, in view of the photoelectric conversion efficiency of the solar cell, the perovskite compound which is used for photoabsorber layer of the solar cell may have a lattice constant of more than 0.6315 nanometers and not more than 0.6363 nanometers without depending on kinds of the organic compound with which the A site is substituted. The results of the above examples also reveal that the diffraction angle 2θ of the position of the cubical crystal (100) peak of the perovskite compound may be not less than 13.92° and less than 14.01° without depending on kinds of the organic compound with which the A site is substituted.

### INDUSTRIAL APPLICABILITY

The photoabsorber of the present disclosure is useful, for example, as a material which is used for a photoabsorber layer of a solar cell provided on a roof.

### REFERENTIAL SIGNS LIST

1, 31 Substrate
2, 22, 32 First Electrode
3 Photoabsorber Layer
4, 34 Second Electrode
5 Electron Transport Layer
6 Porous Layer
7 Hole Transport Layer
8 Template Layer
100, 200, 300, 400, 500, 600, 700 Solar Cell

1. A photoabsorber which has a perovskite crystal structure and is represented by the composition formula ABX₃, wherein
A is a monovalent cation including formamidinium cation A¹ and a nitrogen-containing cation A²;
the nitrogen-containing cation A² has a larger ionic radius than the formamidinium cation A¹;
B is a divalent cation including a Sn cation; and
X is a halogen anion.

2. The photoabsorber according to claim 1, wherein
the photoabsorber is represented by the composition formula A¹₍₁₋ₓ₎A²ₓBX₃; and
the value of x is more than 0 and less than 1.

3. The photoabsorber according to claim 2, wherein
the value of x is not less than 0.05 and not more than 0.5.

4. The photoabsorber according to claim 1, wherein
the photoabsorber is represented by the composition formula ASnX₃.

5. The photoabsorber according to claim 4, wherein the photoabsorber is represented by the composition formula A¹₍₁₋ₓ₎A²ₓSnX₃; and
the value of x is more than 0 and less than 1.

6. The photoabsorber according to claim 5, wherein
the value of x is not less than 0.05 and not more than 0.5.

7. The photoabsorber according to claim 1, wherein
a peak of a diffraction angle 2θ appears within a range of not less than 13.92° and less than 14.01° in an X-ray diffraction measurement result using a CuKα ray.

8. The photoabsorber according to claim 1, wherein
A² is an ethylammonium cation.

9. The photoabsorber according to claim 8, wherein
the following mathematical formula (Ia) is satisfied:
0.05≤[EA]/([FA]+[EA])≤0.6 (Ia)
where
[EA] is a molar number of the ethylammonium cation, and
[FA] is a molar number of the formamidinium cation A¹.

10. The photoabsorber according to claim 9, wherein
the following mathematical formula (Ib) is satisfied:
0.05≤[EA]/([FA]+[EA])≤0.5 (Ib)

11. The photoabsorber according to claim 1, wherein
A² is a guanidinium cation.

12. The photoabsorber according to claim 11, wherein
the following mathematical formula (Ic) is satisfied:
0.091≤[GA]/([FA]+[GA])≤0.455 (Ic)
where
[GA] is a molar number of the guanidinium cation, and
[FA] is a molar number of the formamidinium cation A¹.

13. The photoabsorber according to claim 12, wherein
the following mathematical formula (Id) is satisfied:
0.091≤[GA]/([FA]+[GA])≤0.364 (Id)

14. A solar cell comprising:
a first electrode having a light transmissivity;
a second electrode; and
a photoabsorber layer located between the first electrode and the second electrode;
wherein
the absorber layer contains a photoabsorber according to claim 1.
